(19) United States
(12) Patent Application Publication
(10) Pub. No.: US 2019/0055629 A1
(43) Pub. Date: Feb. 21, 2019

(54) METHOD OF MAKING A TANTALUM SPUTTERING TARGET WITH INCREASED DEPOSITION RATE

(71) Applicant: Tosoh SMD, Inc., Grove City, OH (US)

(72) Inventors: Matt Fisher, Columbus, OH (US); Alex Kuhn, Columbus, OH (US)

(21) Appl. No.: 15/770,600

(22) PCT Filed: Oct. 21, 2016
(86) PCT No.: PCT/US2016/058133

§ 371 Date: Apr. 24, 2018

Related U.S. Application Data
(60) Provisional application No. 62/251,883, filed on Nov. 6, 2015.

(51) Int. Cl. C22C 27/02; C23C 14/34; H01L 21/203

(52) U.S. Cl. CPC C22C 27/02; H01L 21/203; C23C 14/3414

(57) ABSTRACT

Methods of making Ta, Nb, and Ta/Nb sputter targets and targets produced thereby. The improved targets comprise a mixed {100}/{111} texture wherein the % volume of {100} texture is increased over prior art methods and a % volume {111} texture reduced compared to targets made by prior art methods. This results in increased film deposition rates upon sputtering of the improved targets. The methods for manufacturing the improved targets comprise a clock rolling step wherein less than 8% target reduction is achieved at rolling speeds of between about 30-40 rpm.

### CROSS REFERENCE TO RELATED APPLICATION

This application claims the priority benefit of U.S. Provisional Patent Application Ser. No. 62/251,883 filed Nov. 6, 2015.

### FIELD OF INVENTION

The present invention relates to a method of making a tantalum, niobium, or tantalum-niobium alloy, sputtering target wherein, inter alia, the deposition rate is increased compared to prior methods.

### BACKGROUND OF THE INVENTION

The deposition rate of tantalum, niobium, and tantalum-niobium alloy sputtering targets is predominantly controlled by the grain size, and orientation of the grains within the target. As the grain size decreases the deposition rate increases. Zhang, Kho, and Wickersham examined the sputter yield of the three common grain orientations seen in rolled tantalum plate, {100}, {111}, and {110}, in the Effect of grain orientation on tantalum magnetron sputtering yield. They determined that the sputtering yield increases as the grain orientation changes from {111} to {100} to {110}. Deposition rate of each grain orientation increases in the same manner. The orientation of the grains in the tantalum plate, known as texture, has the largest effect on deposition rate.

The starting tantalum material for the prior methods is a grain refined tantalum billet with an average grain size 250 μm or less. A section of this billet is sawed to yield enough material for one target blank. The target blank is upset forged to yield a height reduction at least 50% or greater. After the upset forge step the target blank is clock rolled using a target rolling reduction of 12%. After the clock rolling, the target blank is subjected to a recrystallization vacuum anneal within a range of 1000° C. to 1200° C., to achieve a recrystallization rate 99% or greater. The resulting texture in the tantalum blank is characterized by a mixed {100}, {111}, and {110} texture at the outer edges of the plate, and a {111} texture band at mid thickness of the plate.

### SUMMARY OF THE INVENTION

In certain exemplary embodiments, the invention pertains to a method of making a bcc or bcc metal alloy target. The method comprises the steps of providing a grain refined billet, with an average grain size of about 250 μm or less, cutting a section of the billet to yield enough material to provide one target blank, and then upset forging the blank with a height reduction of at least 50%. The target blank is then clock rolled with a rolling reduction of less than 8%, more preferably between 8-6%, and at a rolling speed of between 30 and 40 rpm. The clock rolled target blank is then vacuum annealed within a temperature range of about 850° C.-1000° C. The desired shape is then imparted to the target blank via machining or the like, and the target blank may optionally be bonded to a backing plate via soldering, diffusion bonding, etc.

The targets in accordance with the invention have an increased volume fraction of {100} oriented grains of 0.300 or greater and a volume fraction of {111} oriented grains of 0.325 or lower. Further, when the targets are sputtered, an increased film deposition rate of about 15.00 angstroms/sec or higher is achieved. In certain embodiments, the bcc metal is tantalum having a purity of 99.5% or greater and a C, O, N, H content of less than 50 ppm. Further, the grain structures of such targets are at least 15% recrystallized.

In other embodiments, niobium targets may be provided wherein the niobium has a purity of 99.5% or greater, a C, O, N, H content of less that 50 ppm, and a grain structure that is at least 15% recrystallized.

In other embodiments, the bcc metal is a tantalum/niobium alloy wherein the alloy has a purity of 99.5% or greater, a C, O, N, H content of less than 50 ppm, and a grain structure that is at least 15% recrystallized.

Thin films, resulting from sputtering of the targets of the present invention, exhibit a variation in film thickness uniformity through the target life (percent non-uniformity of the thin film) of 3% or less. Further, the targets, when sputtered, provide uniform resistivity within and between wafers of 5% or less.

Targets produced in accordance with the invention have an average grain size of about 250 microns or less, more preferably 65 microns or less, and have a texture of oriented grain volume fraction of {100} greater than 0.300 wherein 1.00 equals 100% total grain volume.

In other embodiments, the sputter targets have a texture of oriented grain volume of {111} of less than 0.325 wherein 1.00 equals 100% total grain volume.

In other exemplary embodiments, the sputter target comprises tantalum or alloy having an oriented grain fraction {111} of less than 0.325 wherein 1.00 equals 100% total grain volume.

In other embodiments, the tantalum targets having volume fraction {100} of greater than about 0.325 and wherein the oriented grain fraction {111} is less than about 0.300.

### BRIEF DESCRIPTION OF THE DRAWINGS

FIG. 1 is a graph showing percent of sputtering non-uniform versus target life for target Ex. 1, a target made in accordance with the invention;

FIG. 2 is a graph showing percent variation in film resistivity versus target life for target Ex. 1;

FIG. 3 is a graph showing percent variation in film resistivity versus target life for target Ex. 1;

FIG. 4 is a graph showing volume fraction of {100} oriented grains versus new (the invention) and prior (prior art) methods;

FIG. 5 is a graph showing volume fraction of {111} oriented grains versus new (the invention) and prior (prior art) methods;

FIG. 6 is a graph showing volume fraction of {110} oriented grains versus new (the invention) and prior (prior art) methods; and

FIG. 7 are through texture EBSD texture maps of Ta plates processed using the prior art process and the process of the present invention. FIG. 7a shows the prior art process, characterized by a mixed {100}, {111}, and {110} texture at the outer edges of the plate, and a {111} texture band at mid thickness of the plate. FIG. 7b shows the present inventive process, characterized by an increased volume fraction of {100}, a decreased volume fraction of {111}, and a reduced {111} texture band at mid thickness of the plate.

### DETAILED DESCRIPTION

The starting tantalum material is a grain refined tantalum billet with an average grain size 250 μm or less. A section of this billet is sawed to yield enough material for one target blank. The target blank is upset forged, to yield a height reduction at least 50% or greater. After the upset forged step the target blank is clock rolled using rolling reductions 8% or less, with the target rolling reduction of 6%, and a rolling speed of 36 RPM. The resulting target blank is subjected to a recrystallization vacuum anneal, between 850° C. and 1000° C., to achieve a recrystallization rate 15% or greater. The lower rolling reduction, rolling speed of 36 RPM and lower final anneal temperature compared to prior methods results in a tantalum blank characterized by an increased volume fraction of {100}, and a decreased volume fraction {111}. The combination of an increased volume fraction of {100} oriented grains and a decreased volume fraction of {111} oriented grains, leads to an increased overall deposition rate.

Table 1 shows the metallurgical and sputtering data from two tantalum targets, one manufactured using the prior method, one manufactured using the new method. As shown in Table 1, the volume fraction of {100} planes increased from 0.228 when manufacturing using the prior method, to 0.301 when manufacturing using the new method. The volume fraction of {111} planes decreased from 0.389 when manufacturing using the prior method, to 0.321 when manufacturing using the new method. The average deposition rate through target life increased from 6.600 angstroms/second when manufacturing using the prior method to 18.39 angstroms/second when manufacturing using the new method.

TABLE 1
Processing, metallurgical, and sputtering data from targets C-1 and Ex. 1 manufactured using
the prior and new processes respectively.

| | | Average | Grain | | | | | |
|---|---|---|---|---|---|---|---|---|
| Target Lot | | Rolling | Size (μm) | | Volume Fraction | | | Average Deposition |
| Number | Method | Reduction | Surface | Half | {100} | {111} | {110} | Rate (Angstroms/sec) |
| C-1 104 | Prior | 10.10% | 69.7 | 66 | 0.228 | 0.389 | 0.035 | 6.600 |
| Ex. 1 119 | New | 6.03% | 53.9 | 57.5 | 0.301 | 0.321 | 0.031 | 18.359 |

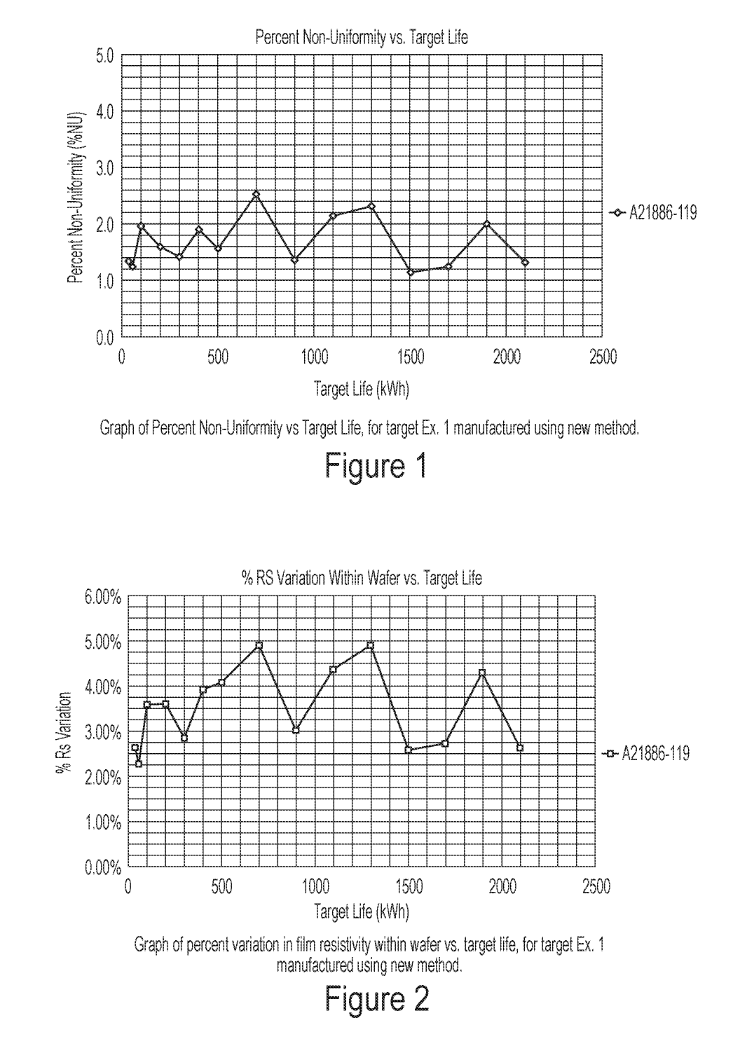

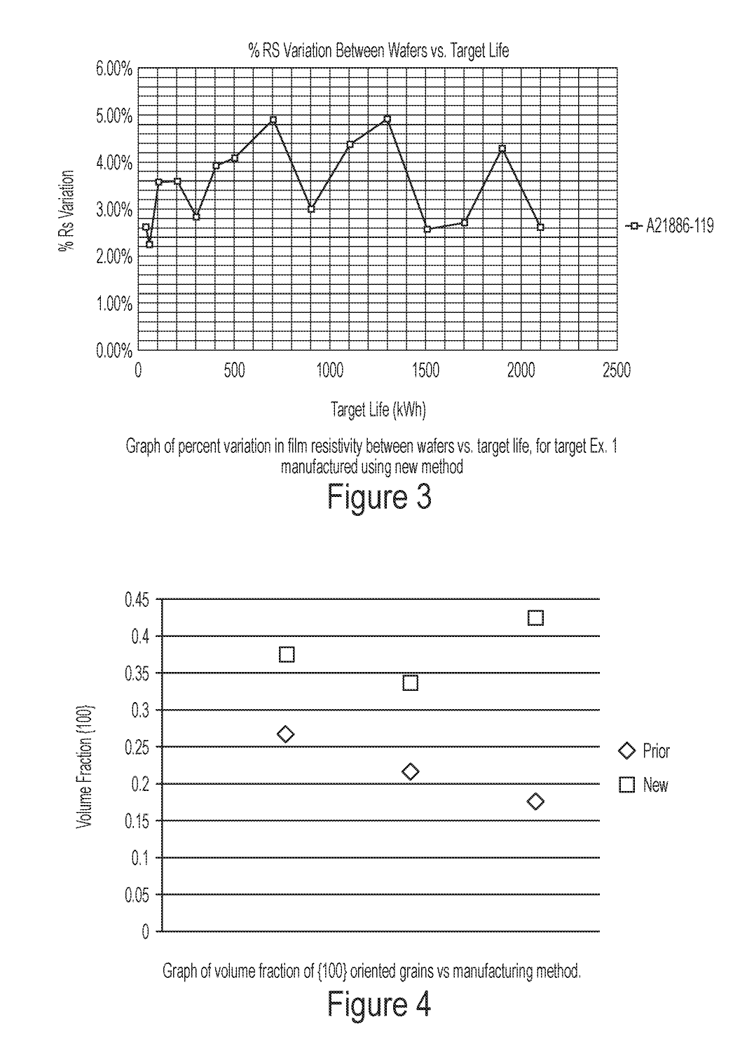

As FIGS. 1, 2, and 3 show, target Ex.1 manufactured using the new method, exhibits excellent thin film characteristics. The percent non-uniformity was below 3% through target life and the percent variation in film resistivity within wafers and between wafers was below 5% through target life.

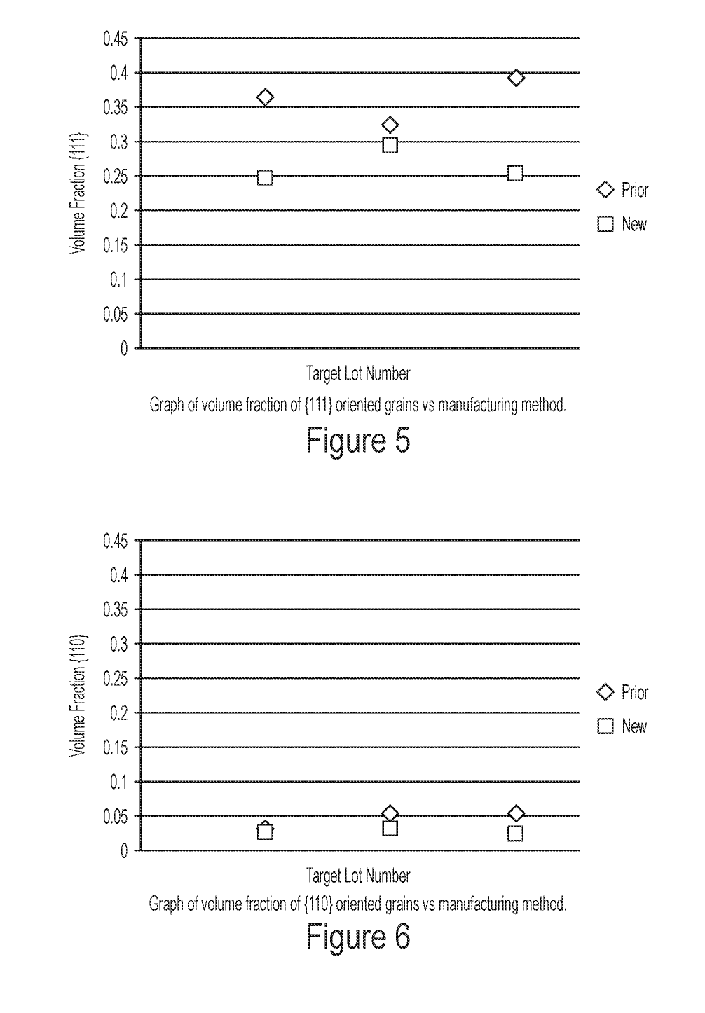

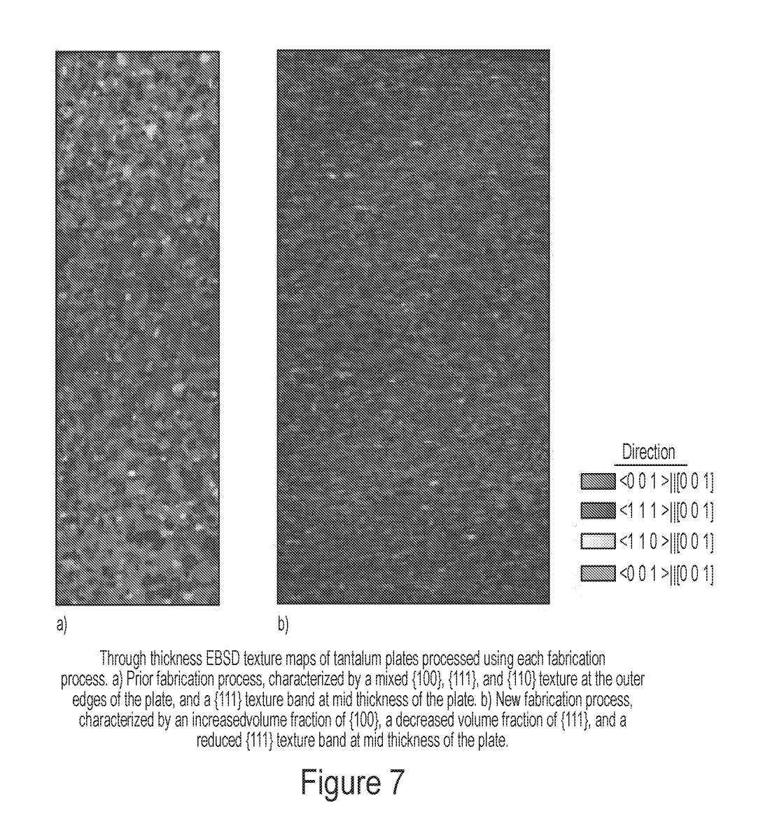

Table 2 shows the metallurgical data from three targets manufactured using the prior method, and three targets manufactured using the new method. Sputtering data was not gathered for these targets. FIGS. 4, 5, and 6 plot the volume fraction of {100}, {111}, and {110} oriented grains comparing the prior method and new method. It is clear that the new method increases, the volume fraction of {100} oriented grains, and decreases the volume fraction of {111} oriented grains. The volume fraction of {110} oriented grains appears to not be affected. The benefit of a sputtering target with an increased deposition rate is improved step coverage when depositing thin films.

TABLE 2
Processing, metallurgical, and sputtering data from targets
manufactured using the prior and new processes.

| | | | Grain | | | | |
|---|---|---|---|---|---|---|---|
| Target Lot | | Average Rolling | Size (μm | | Volume Fraction | | |
| Number | Method | Reduction | Surface | Half | {100} | {111} | {110} |
| C-2 118 | Prior | 12.50% | 46.5 | 50.7 | 0.267 | 0.362 | 0.032 |
| C-1 104 | Prior | 12.50% | 52.9 | 47.2 | 0.216 | 0.324 | 0.053 |
| C-3 101 | Prior | 12.50% | 63.2 | 67.6 | 0.177 | 0.393 | 0.052 |
| Ex. 2 109 | New | 6.03% | 47.4 | 64.4 | 0.374 | 0.248 | 0.027 |
| Ex. 1 119 | New | 6.03% | 18.7 | 29.1 | 0.337 | 0.295 | 0.03 |
| Ex. 3 105 | New | 6.13% | 39.3 | 38.5 | 0.423 | 0.254 | 0.024 |

While the present invention has been described with respect to specific examples, it is apparent that numerous other forms and modifications of the invention will be obvious to those skilled in the art. The appended claims and this invention should be construed to cover all such obvious forms and modifications which are within the spirit and scope of the present invention.

1. A method of making a BCC metal or BCC metal alloy target, said method comprising the following steps:
a) providing a grain refined billet, with an average grain size of 250 μm or less
b) cutting a section of this billet to yield enough material for one target blank, and upset forging said blank with a height reduction of at least 50%
c) clock rolling said target blank with a rolling reduction of less than 8% and a rolling speed between 30 and 40 rpm; and
d) vacuum annealing said target blank within a temperature range of 850° C. to 1000° C.

2. The method as recited in claim 1, wherein said rolling reduction in step c) is between about 6 to about 8%.

3. The method as recited in claim 1, wherein said target has a volume fraction of {100} oriented grains of 0.300 or greater, and a volume fraction of {111} oriented grains of 0.325 or lower.

4. A BCC metal or BCC metal alloy sputtering target manufactured using the method recited in claim 1, having a deposition rate 15.000 angstroms/sec or higher.

5. The method as recited in claim 1, wherein said BCC metal is tantalum, wherein said tantalum has a purity 99.5% or greater, a C, O, N, H content of less than 50 ppm, and a grain structure that is at least 15% recrystallized.

6. The method as recited in claim 1, wherein said BCC metal is niobium, wherein said niobium has a purity 99.5% or greater, a C, O, N, H content of less than 50 ppm, and a grain structure that is at least 15% recrystallized.

7. The method as recited in claim 1, wherein said BCC metal is a tantalum-niobium alloy, wherein said tantalum-niobium alloy has a purity 99.5% or greater, a C, O, N, H content of less than 50 ppm, and a grain structure that is at least 15% recrystallized.

8. A thin film for semiconductor applications created by using the BCC metal or metal alloy sputtering target according to claim 1, where variation in film thickness uniformity through target life (percent non-uniformity) of said thin film is 3% or less.

9. A thin film for semiconductor application created by using the BCC metal or metal alloy sputtering target according to claim 1, where percent variation in film resistivity is 5% or less.

10. A sputter target composed of BCC metal or alloy, said target having an average grain size of 250 μm or less, said target having a texture of oriented grain volume fraction of {100} greater than 0.300 wherein 1.00 equals 100% total grain volume.

11. The sputter target as recited in claim 10, wherein said target has a texture of oriented grain volume fraction of {111} less than 0.325 wherein 1.00 equals 100% total grain volume.

12. The sputter target as recited in claim 10, wherein said BCC metal or alloy is Ta having an oriented grain fraction of less than 0.325 wherein 1.00 equals 100% total grain volume.

13. The sputter target as recited in claim 12, wherein said oriented grain volume fraction {100} is greater than about 0.325 and wherein said oriented grain volume fraction {111} is less than about 0.300.
